(19) United States
(12) Patent Application Publication
(10) Pub. No.: US 2025/0289833 A1
(43) Pub. Date: Sep. 18, 2025

(54) CYCLOSILAZANE COMPOUND AND METHOD OF PRODUCING SILICON-CONTAINING THIN FILM USING THE SAME

(71) Applicant: DNF CO., LTD., Daejeon (KR)

(72) Inventors: Se Jin JANG, Daejeon (KR); Sung Gi KIM, Daejeon (KR); In Kyung JUNG, Daejeon (KR); Jeong Joo PARK, Daejeon (KR); Jun Hee CHO, Daejeon (KR); Gun Joo PARK, Daejeon (KR); Haeng Don LIM, Daejeon (KR)

(21) Appl. No.: 19/066,483

(22) Filed: Feb. 28, 2025

(30) Foreign Application Priority Data
Mar. 14, 2024 (KR) 10-2024-0035678

(51) Int. Cl. C07F 7/08; C23C 16/30

(52) U.S. Cl. CPC C07F 7/0816; C23C 16/30

(57) ABSTRACT

A cyclosilazane compound, a composition for depositing a silicon-containing thin film including the same, and a method of producing a silicon-containing thin film using the same are described. The silicon-containing thin film produced using the cyclosilazane compound as a silicon precursor has both excellent chemical and thermal stability and has a low dielectric constant. Therefore, it may be usefully applied as an insulating film of a semiconductor device, in particular, a spacer of a semiconductor miniaturization process.

### CROSS-REFERENCE TO RELATED APPLICATIONS

This application claims priority under 35 U.S.C. § 119 to Korean Patent Application No. 10-2024-0035678, filed on Mar. 14, 2024, in the Korean Intellectual Property Office, the disclosure of which is incorporated herein by reference in its entirety.

### TECHNICAL FIELD

The following disclosure relates to a cyclosilazane compound used as a precursor of a low-dielectric silicon-containing thin film, a composition for depositing a silicon-containing thin film including the same, and a method of producing a silicon-containing thin film using the same.

### BACKGROUND

A silicon thin film produced by various deposition methods such as atomic layer deposition (ALD) and chemical vapor deposition (CVD) is being used as a semiconductor substrate, a diffusion mask, an anti-oxidation film and a dielectric film, an insulating film, and the like in semiconductor technology.

Meanwhile, it is important for an insulating film for a spacer of a semiconductor device to have a low-dielectric constant and excellent corrosion resistance, and furthermore, in order to apply it to an actual process, conditions such as ease of process and excellent chemical and thermal stability should be satisfied, and thus, the physical properties required for the insulating film for a spacer which is applied to a next-generation semiconductor device are gradually advanced.

To this end, studies for lowering the dielectric constant of the silicon thin film continue, but a sufficiently low dielectric constant is not secured or thermal stability and corrosion resistance are reduced, and productivity decreases due to a low thin film formation rate. In addition, as a method of satisfying both the low dielectric rate and corrosion resistance of the silicon thin film, a method of doping fluorine (F) after forming a silicon-containing thin film has been suggested. However, the method further involves a fluorine doping step which makes the process complicated, the doping proceeds mainly only near the surface of the thin film, making it difficult to perform F doping in an area deeper than the surface, and thus, the quality of the thin film is deteriorated.

### RELATED ART DOCUMENTS

### Patent Document

(Patent Document 1) Korean Patent Laid-Open Publication No. 10-2002-0063196 (Aug. 1, 2002)

### SUMMARY

An embodiment of the present invention is directed to providing a cyclosilazane compound used as a precursor of a high-quality and low-dielectric silicon-containing thin film, and a composition for depositing a silicon-containing thin film including the same.

Another embodiment of the present invention is directed to providing a method of producing a silicon-containing thin film, which allows deposition of a thin film with a high thin film deposition rate even under mild conditions and production of a high-quality thin film with a high yield.

In one general aspect, a cyclosilazane compound represented by the following Chemical Formula 1 is provided:

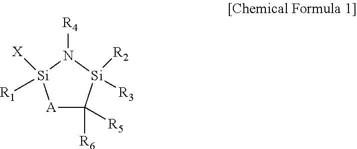

wherein
X is halogen;
R₁ to R₃ are independently of one another hydrogen, halogen, C1-C7 alkyl, C2-C7 alkenyl, or C2-C7 alkynyl;
R₄ is hydrogen, halogen, C1-C7 alkyl, C2-C7 alkenyl, C2-C7 alkynyl, or —Si(R₁₁)(R₁₂)(R₁₃);
A is —(CR₇R₈)ₙ—;
R₅ to R₈ and R₁₁ to R₁₃ are independently of one another hydrogen, C1-C7 alkyl, C2-C7 alkenyl, or C2-C7 alkynyl; and
n is an integer of 1 to 5.

X may be fluoro; R₁ to R₃ may be independently of one another hydrogen, fluoro, C1-C4 alkyl, C2-C4 alkenyl, or C2-C4 alkynyl; R₄ may be hydrogen, fluoro, C1-C4 alkyl, C2-C4 alkenyl, C2-C4 alkynyl, or —Si(R₁₁)(R₁₂)(R₁₃); A may be-(CR₇R₈)ₙ—; R₅ to R₈ and R₁₁ to R₁₃ may be independently of one another hydrogen, C1-C4 alkyl, C2-C4 alkenyl, or C2-C4 alkynyl; and n may be an integer of 1 to 3.

The cyclosilazane compound according to an exemplary embodiment may be represented by the following Chemical Formula 2:

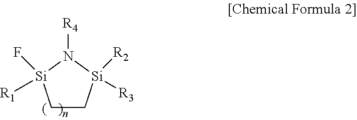

wherein
R₁ to R₃ are independently of one another hydrogen, fluoro, C1-C7 alkyl, C2-C7 alkenyl, or C2-C7 alkynyl;
R₄ is hydrogen, fluoro, C1-C7 alkyl, C2-C7 alkenyl, C2-C7 alkynyl, or —Si(R₁₁)(R₁₂)(R₁₃);
R₁₁ to R₁₃ are independently of one another hydrogen, C1-C7 alkyl, C2-C7 alkenyl, or C2-C7 alkynyl; and
n is an integer of 1 to 5.

R₁ to R₃ may be independently of one another hydrogen, fluoro, or C1-C4 alkyl; R₄ may be hydrogen, fluoro, C1-C4 alkyl, or —Si(R₁₁)(R₁₂)(R₁₃); R₁₁ to R₁₃ may be independently of one another hydrogen or C1-C4 alkyl; and n may be an integer of 1 to 3.

The cyclosilazane compound according to an exemplary embodiment may be represented by the following Chemical Formula 3:

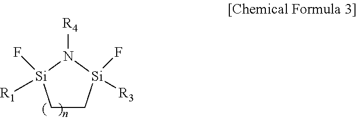

wherein
R₁ and R₃ are independently of each other hydrogen, fluoro, C1-C7 alkyl, C2-C7 alkenyl, or C2-C7 alkynyl;
R₄ is hydrogen, fluoro, C1-C7 alkyl, C2-C7 alkenyl, C2-C7 alkynyl, or —Si(R₁₁)(R₁₂)(R₁₃);
R₁₁ to R₁₃ are independently of one another hydrogen, C1-C7 alkyl, C2-C7 alkenyl, or C2-C7 alkynyl; and
n is an integer of 1 to 5.

R₁ and R₃ may be independently of each other hydrogen, fluoro, or C1-C4 alkyl; R₄ may be hydrogen, fluoro, C1-C4 alkyl, or —Si(R₁₁)(R₁₂)(R₁₃); R₁₁ to R₁₃ may be independently of one another hydrogen or C1-C4 alkyl; and n may be an integer of 1 to 3.

The cyclosilazane compound according to an exemplary embodiment may be selected from the following structures:

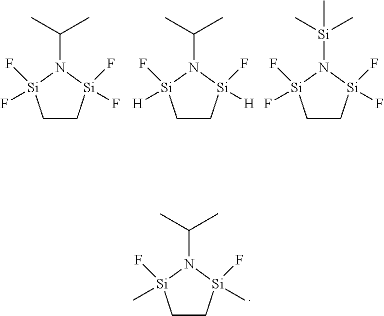

In another general aspect, a composition for depositing a silicon-containing thin film includes the cyclosilazane compound.

In still another general aspect, a method of producing a silicon-containing thin film, which uses a cyclosilazane compound represented by the following Chemical Formula 1 or a composition for depositing a silicon-containing thin film including the compound is provided:

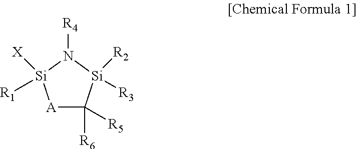

wherein
R₁ to R₆, X, and A are as defined above.

The silicon-containing thin film may be a fluorine and silicon-containing thin film.

The silicon-containing thin film may contain 0.5 at % or more of fluorine.

Other features and aspects will be apparent from the following detailed description, the drawings, and the claims.

### BRIEF DESCRIPTION OF THE DRAWINGS

FIG. 1 shows TGA and DSC analysis results of 2,2,5,5-tetrafluoro-1-isopropyl-[1,2,5]-azadisilacyclopentane produced in Example 1.

### DETAILED DESCRIPTION OF EMBODIMENTS

In the present specification, unless otherwise defined, all technical terms and scientific terms have the same meanings as those commonly understood by a person skilled in the art to which the present invention pertains. The terms used herein are only for effectively describing a certain specific example and are not intended to limit the present invention.

The singular form used in the present specification may be intended to also include a plural form, unless otherwise indicated in the context.

Throughout the present specification, unless otherwise particularly stated, “comprising”, “being equipped with”, “containing”, or “having” a constituent element does not mean excluding any other constituent element, but mean the further including other constituent elements, and elements, materials, or processes which are not further listed are not excluded.

The numerical range used in the present specification includes all values within the range including the lower limit and the upper limit, increments logically derived from the form and spanning of a defined range, all double limited values, and all possible combinations of the upper limit and the lower limit in the numerical range defined in different forms. Unless otherwise defined in the present specification, values which may be outside a numerical range due to experimental error or rounding off of a value are also included in the defined numerical range.

Unless otherwise particularly defined in the present specification, “about” may be considered as a value within 30%, 25%, 20%, 15%, 10%, or 5% of a stated value.

The term “alkyl” in the present specification is an organic radical derived from an aliphatic hydrocarbon by removal of one hydrogen, and may include both linear and branched alkyls. The alkyl may have 1 to 7, specifically 1 to 5, and more specifically 1 to 4 carbon atoms. The linear alkyl may include, as an example, methyl, ethyl, n-propyl, n-butyl, n-pentyl, n-hexyl, and n-heptyl, and the branched alkyl may include isopropyl, sec-butyl, isobutyl, tert-butyl, isopentyl, 2-methylhexyl, 3-methylbutyl, 2-methylpentyl, 3-methylpentyl, 4-methylpentyl, 2-methylhexyl, 3-methylhexyl, 4-methylhexyl, 5-methylhexyl, 2,3-dimethylbutyl, 2,3-dimethylpentyl, 2,4-dimethylpentyl, and the like, but is not limited thereto.

The term “alkenyl” in the present specification refers to a linear or branched unsaturated hydrocarbon radical including one or more double bonds, and “alkynyl” refers to a linear or branched unsaturated hydrocarbon radical including one or more triple bonds.

Hereinafter, the present disclosure will be described in detail. However, it is only illustrative, and the present disclosure is not limited to the specific exemplary embodiment which is illustratively described.

An exemplary embodiment of the present invention provides a cyclosilazane compound used as a precursor of a high-quality low-dielectric silicon-containing thin film.

Specifically, the cyclosilazane compound according to an exemplary embodiment may be represented by the following Chemical Formula 1:

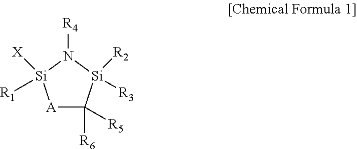

wherein
X is halogen;
R₁ to R₃ are independently of one another hydrogen, halogen, C1-C7 alkyl, C2-C7 alkenyl, or C2-C7 alkynyl;
R₄ is hydrogen, halogen, C1-C7 alkyl, C2-C7 alkenyl, C2-C7 alkynyl, or —Si(R₁₁)(R₁₂)(R₁₃);
A is —(CR₇R₈)ₙ—;
R₅ to R₈ and R₁₁ to R₁₃ are independently of one another hydrogen, C1-C7 alkyl, C2-C7 alkenyl, or C2-C7 alkynyl; and
n is an integer of 1 to 5, and when n is an integer of 2 or more, R₇ and R₈ may be different from each other.

Since the cyclosilazane compound according to an exemplary embodiment has the structural characteristics of Chemical Formula 1, for example, a ring structure including a disilazane group (*—Si—N—Si—*) and at least one or more halogen (F, Cl, Br, I) substituents, it is present in a liquid state at room temperature, may have excellent volatility properties and thermal stability, allows deposition of a thin film with a high thin film deposition rate even under low temperature conditions, and may provide a low-dielectric thin film having high purity and excellent durability.

As an example, X may be fluoro (—F).

As an example, R₁ to R₃ may be independently of one another hydrogen, fluoro, C1-C4 alkyl, C2-C4 alkenyl, or C2-C4 alkynyl; R₄ may be hydrogen, fluoro, C1-C4 alkyl, C2-C4 alkenyl, C2-C4 alkynyl, or —Si(R₁₁)(R₁₂)(R₁₃); A may be —(CR₇R₈)ₙ—; R₅ to R₈ and R₁₁ to R₁₃ may be independently of one another hydrogen, C1-C4 alkyl, C2-C4 alkenyl, or C2-C4 alkynyl; and n may be an integer of 1 to 3.

Specifically, the cyclosilazane compound according to an exemplary embodiment may be represented by the following Chemical Formula 2:

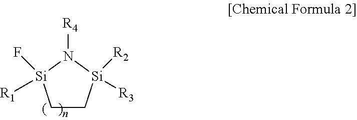

wherein
R₁ to R₃ are independently of one another hydrogen, fluoro, C1-C7 alkyl, C2-C7 alkenyl, or C2-C7 alkynyl;
R₄ is hydrogen, fluoro, C1-C7 alkyl, C2-C7 alkenyl, C2-C7 alkynyl, or —Si(R₁₁)(R₁₂)(R₁₃);
R₁₁ to R₁₃ are independently of one another hydrogen, C1-C7 alkyl, C2-C7 alkenyl, or C2-C7 alkynyl; and
n is an integer of 1 to 5.

As an example, R₁ to R₃ may be independently of one another hydrogen, fluoro, or C1-C4 alkyl; R₄ may be hydrogen, fluoro, C1-C4 alkyl, or —Si(R₁₁)(R₁₂)(R₁₃); R₁₁ to R₁₃ may be independently of one another hydrogen or C1-C4 alkyl; and n may be an integer of 1 to 3.

Specifically, the cyclosilazane compound according to an exemplary embodiment may be represented by the following Chemical Formula 3:

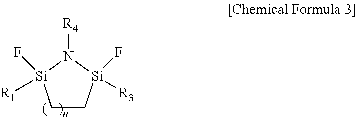

wherein
R₁ and R₃ are independently of each other hydrogen, fluoro, C1-C7 alkyl, C2-C7 alkenyl, or C2-C7 alkynyl;
R₄ is hydrogen, fluoro, C1-C7 alkyl, C2-C7 alkenyl, C2-C7 alkynyl, or —Si(R₁₁)(R₁₂)(R₁₃);
R₁₁ to R₁₃ are independently of one another hydrogen, C1-C7 alkyl, C2-C7 alkenyl, or C2-C7 alkynyl; and
n is an integer of 1 to 5.

As an example, in Chemical Formula 3, R₁ and R₃ may be independently of each other hydrogen, fluoro, or C1-C4 alkyl; R₄ may be hydrogen, fluoro, C1-C4 alkyl, or —Si(R₁₁)(R₁₂)(R₁₃); R₁₁ to R₁₃ may be independently of one another hydrogen or C1-C4 alkyl; and n is an integer of 1 to 3.

As an example, R₁ and R₃ may be independently of each other hydrogen, fluoro, or methyl.

As an example, R₁ and R₃ may be identical to each other and be hydrogen, fluoro, or C1-C4 alkyl, or methyl.

As an example, R₄ may be hydrogen, fluoro, C1-C4 alkyl, or —Si(R₁₁)(R₁₂)(R₁₃); R₁₁ to R₁₃ may be independently of one another hydrogen or C1-C4 alkyl; and n may be an integer of 1 to 3.

As an example, R₁₁ to R₁₃ may be identical to each other and be hydrogen, C1-C4 alkyl, or methyl.

As an example, R₄ may be hydrogen, fluoro, branched (C3-C7) alkyl, or —Si(R₁₁)(R₁₂)(R₁₃), and for example, the branched (C3-C7) alkyl may be isopropyl, sec-butyl, isobutyl, tert-butyl, or isopentyl.

As an example, n may be 1 or 2.

The cyclosilazane compound according to an exemplary embodiment may be, for example, selected from the following structures, but is not limited thereto:

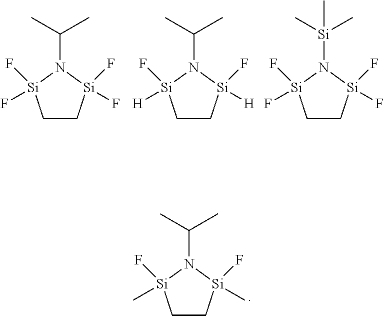

Hereinafter, the method of producing the cyclosilazane compound represented by Chemical Formula 1 will be described in detail, but the compound may be synthesized also by a method which may be recognized by a person skilled in the art, of course, an organic solvent used herein is not limited, and a reaction time and temperature may be also changed within a range which does not depart from the gist of the invention, of course.

The method of producing the cyclosilazane compound represented by Chemical Formula 1 according to an exemplary embodiment may include (A) a step of reacting a compound represented by the following Chemical Formula 11 with a compound represented by the following Chemical Formula 12:

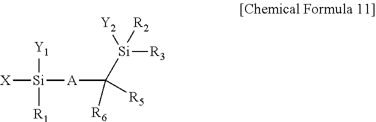

R₄—NH₂ (12)

wherein
Y₁ and Y₂ are independently of each other Cl or Br; and
R₁ to R₆, X, and A are as defined in Chemical Formula 1.

In addition, the method of producing the cyclosilazane compound represented by Chemical Formula 1 according to an exemplary embodiment may further include (B) step of reacting a fluorine source, after step (A).

Step (A) may be performed at 0 to 30° C. for 1 hour to 10 hours, specifically 10 to 30° C. for 1 to 5 hours, but is not limited thereto, and may be changed depending on the reaction material, the type of solvent, and the amount of use.

The fluorine source may be selected from alkali metal fluorides such as LiF, KF, NaF, RbF, and CsF, or transition metal fluorides such as AgF, AgF₂, ZnF₂, CuF₂, CuF₂·H₂O, NiF₂, SnF₂, InF₃, ScF₃, TiF₃, MnF₃, CoF₃, CrF₃, AuF₃, FeF₃, MnF₃, BiF₃, and SbF₃, but is not limited thereto.

In addition, step (B) may be performed at 30 to 70° C. for 5 to 20 hours, specifically 40 to 60° C. for 10 to 20 hours, but is not limited thereto, and may be changed depending on the reaction material, and the type and the used amount of the solvent.

Another exemplary embodiment of the present invention provides a composition for depositing a silicon-containing thin film including the cyclosilazane compound.

The composition for depositing a silicon-containing thin film according to an exemplary embodiment includes the cyclosilazane compound represented by Chemical Formula 1 as a precursor for depositing a thin film, and the content of the compound represented by Chemical Formula 1 in the composition may be included within a range which may be recognized by a person skilled in the art considering the film formation conditions of a thin film, the thickness of a thin film, the characteristics of a thin film, the use of a thin film, and the like.

Another exemplary embodiment of the present invention provides a method of producing a silicon-containing thin film, which uses a cyclosilazane compound represented by the following Chemical Formula 1 or a composition for depositing a silicon-containing thin film including the compound:

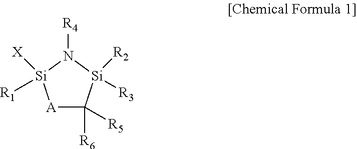

wherein
R₁ to R₆, X, and A are as defined in Chemical Formula 1.

Since the method of producing a silicon-containing thin film according to an exemplary embodiment uses the cyclosilazane compound represented by Chemical Formula 1 as a precursor, a high-quality silicon-containing thin film may be produced with a high deposition rate even at a low temperature and low power.

Specifically, the silicon-containing thin film according to an exemplary embodiment may be a fluorine and silicon-containing thin film, and in the method of producing a silicon-containing thin film according to an exemplary embodiment, when the cyclosilazane compound represented by Chemical Formula 1 contains fluorine (F), fluorine (F) of the cyclosilazane compound remains in the thin film, and a low-dielectric and high-quality fluorine and silicon-containing thin film may be provided.

Specifically, the silicon-containing thin film according to an exemplary embodiment may contain 0.5 at % or more, 1.0 at % or more, 1.5 at % or more, 2.0 at % or more, 2.5 at % or more and 10 at % or less, 9 at % or less, 8 at % or less, or 7 at % or less of fluorine.

The cyclosilazane compound according to an exemplary embodiment may produce a thin film containing both fluorine and silicon as one precursor. That is, generally, a fluorine and silicon-containing thin film is obtained by producing a silicon-containing thin film and then doping fluorine using a fluorine-containing precursor, but in this case, a fluorine content in the thin film may be non-uniform. However, the method of producing a silicon-containing thin film of the present invention may overcome the disadvantage to produce a fluorine and silicon-containing thin film having a uniform fluorine content with one precursor.

In the method of producing a silicon-containing thin film according to an exemplary embodiment, the cyclosilazane compound and the reaction gas may be supplied organically or independently of each other. In addition, the cyclosilazane compound and the reaction gas may be continuously or discontinuously supplied, and discontinuous supply may include a pulse form.

As an example, the method of producing a silicon-containing thin film may include:
a) maintaining a temperature of a substrate mounted in a chamber at 100° C. or higher;
b) adsorbing the cyclosilazane compound represented by Chemical Formula 1 or a composition for depositing a silicon-containing thin film including the compound onto the substrate; and
c) injecting a reaction gas into the substrate on which the cyclosilazane compound or the composition for depositing a silicon-containing thin film including the compound is adsorbed to deposit a silicon-containing thin film.

Specifically, the method of producing a silicon-containing thin film may include:
a) maintaining a temperature of a substrate mounted in a chamber at 100° C. or higher;
b) adsorbing the cyclosilazane compound represented by Chemical Formula 1 or a composition for depositing a silicon-containing thin film onto the substrate;
c) purging a residual cyclosilazane compound or a residual composition for depositing a thin film and a by-product;
d) injecting a reaction gas into the substrate on which the cyclosilazane compound or the composition for depositing a thin film including the compound is adsorbed to form a silicon-containing thin film; and
e) purging a residual reaction gas and by-products.

In addition, as an example, the method of producing a silicon-containing thin film may include:
maintaining a temperature of a substrate mounted in a chamber at 100° C. or higher; and
injecting the cyclosilazane compound represented by Chemical Formula 1 or a composition for depositing a silicon-containing thin film including the compound and a reaction gas simultaneously to deposit a silicon-containing thin film.

The deposition method is not particularly limited as long as it is commonly used in the art, but, for example, thermal chemical vapor deposition (TVCD), atomic layer deposition (ALD), chemical vapor deposition (CVD), metal organic chemical vapor deposition (MOCVD), low pressure chemical vapor deposition (LPCVD), plasma enhanced chemical vapor deposition (PECVD), or plasma enhanced atomic layer deposition (PEALD) may be used, but is not limited thereto.

The type of reaction gas is not particularly limited as long as it is commonly used in the art, but as an example, may be oxygen (O₂), ozone (O₃), oxygen plasma, hydrogen (H₂), hydrogen plasma, water (H₂O), hydrogen peroxide (H₂O₂), nitrogen dioxide (NO₂), nitrogen monoxide (NO), nitrous oxide (N₂O), ammonia (NH₃), carbon dioxide (CO₂), formic acid (HCOOH), acetic acid (CH₃COOH), anhydrous acetic acid ((CH₃CO)₂O), or a combination thereof. A gas for purging may be nitrogen (N₂), argon (Ar), helium (He), or a combination thereof.

Though the substrate is not particularly limited as long as it is commonly used in the art, it may be, for example, a substrate including one or more semiconductor materials among Si, Ge, SiGe, GaP, GaAs, SiC, SiGeC, InAs, and InP; a silicon on insulator (SOI) substrate; a quartz substrate; a glass substrate for display; or a flexible plastic substrate such as polyimide (PI), polyethylene terephthalate (PET), polyethylene naphthalate (PEN), polymethyl methacrylate (PMMA), polycarbonate (PC), polyethersulfone (PES), and polyester.

In addition, the silicon-containing thin film may be formed directly on the substrate, but also, a plurality of conductive layers, dielectric layers, insulating layers, or the like may be further formed between the substrate and the silicon-containing thin film.

As an example, a temperature of the substrate may be specifically 100 to 1,000° C., 300 to 1,000° C., or 500 to 1,000° C., and under the temperature conditions, fluorine (F) of the cyclosilazane compound represented by Chemical Formula 1 may be allowed to remain in the thin film, a high-quality fluorine and silicon-containing thin film may be provided, and a thin film having a lower dielectric constant may be provided.

As an example, the reaction gas may be supplied after being activated by generating plasma at 50 to 1,000 W, 100 to 800 W, or 400 to 600 W.

That is, the method of producing a silicon-containing thin film according to an exemplary embodiment uses the compound of Chemical Formula 1 as a precursor, thereby effectively producing a thin film even at a low temperature and with low plasma. In addition, an exemplary embodiment of the present invention provides a silicon-containing thin film produced from the production method.

The silicon-containing thin film according to an exemplary embodiment may be any thin film which is produced within a range which may be recognized by a person skilled in the art, and specifically, may be a fluorosilicon carbide film, a fluorosilicon oxide film, a silicon fluoride film, a silicon carbide film, and the like, and other than that, various high-quality thin films containing silicon may be produced within a range which may be recognized by a person skilled in the art.

Since the silicon-containing thin film according to an exemplary embodiment has a very low dielectric constant as well as both excellent chemical and thermal stability, it may be used for various uses, for example, an insulating film, a diffusion barrier, a spacer, an intermetallic dielectric material, a protective layer, and the like.

Hereinafter, the exemplary embodiments described above will be described in detail through the following examples. However, the following examples are only for description, and do not limit the right scope.

The physical properties of the examples were measured as follows:

### 1) Thermal Properties

In order to measure the thermal stability, the volatility, and the decomposition temperature of the cyclosilazane compound, thermogravimetric analysis (TGA, L81-II, LINSEIS) and differential scanning calorimeter (DSC) were used.

### <Production of Cyclosilazane Compound>

### EXAMPLE 1

### 2,2,5,5-Tetrafluoro-1-isopropyl-[1,2,5]azadisilacyclopentane

Step 1: Synthesis of 1,2-bis(trichlorosilyl)ethane

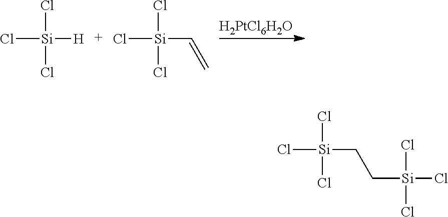

A reflux device was installed in a flame-dried 1 L flask under an anhydrous inert atmosphere, 310 g (2.29 mol) of trichlorosilane and 0.1 g (0.2 mmol) of chloroplatinic acid (H₂PtCl₆·6H₂O) were added, and the temperature was raised to 70° C. 351.1 g (2.17 mol) of trichlorovinylsilane was slowly added thereto, and stirring was performed for 2 hours to complete the reaction. The reaction mixture was distilled under reduced pressure under 80° C. and 1.5 torr conditions to obtain 630 g of 1,2-bis(trichlorosilyl)ethane (yield: 98%, 2.12 mol).

¹H NMR (C₆D₆): 1.04 ppm (s, 4H, Si—CH₂—CH₂—Si)

Step 2: Synthesis of 2,2,5,5-Tetrachloro-1-isopropyl-[1,2,5]azadisilacyclopentane

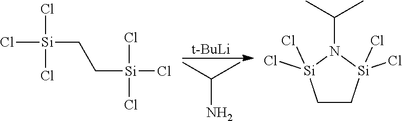

630 g (2.12 mol) of 1,2-bis (trichlorosilyl) ethane and 548 g (6.36 mol) of n-hexane were added to a flame-dried 5 L flask under an anhydrous inert atmosphere, the temperature was lowered to-30° C. or lower, and 3120 mL (5.3 mol) of 1.7 M tert-butyl lithium was slowly added. After completing the addition, the temperature was slowly raised to 0° C. or lower, stirring was performed for 1 hour, and 150 g (2.55 mol) of isopropylamine was slowly added. During the addition, internal temperature was maintained at 15° C. or lower. After the addition was completed, the temperature was slowly raised to room temperature, and stirring was performed for 2 hours to complete the reaction. The reaction mixture was filtered, and the filtrate was distilled under reduced pressure under 50° C. and 0.8 torr conditions to obtain 176 g (0.62 mol) of 2,2,5,5-tetrachloro-1-isopropyl-[1,2,5]azadisilacyclopentane (yield: 29%, GC purity: 93.9%).

¹H NMR (C₆D₆): 0.88 ppm (s, 4H, Si—CH₂—CH₂—Si), 1.26 ppm (d, 6H, N—CH(CH₃)₂), 3.58 ppm (m, 1H N—CH(CH₃)₂),

Step 3: Synthesis of 2,2,5,5-Tetrafluoro-1-isopropyl-[1,2,5]azadisilacyclopentane

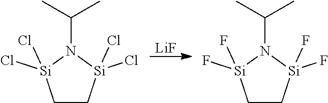

250 g (1.87 mol) of diethylene glycol dimethyl ether and 96.91 g (3.74 mol) of lithium fluoride were added to a flame-dried 1 L flask under an anhydrous inert atmosphere, the temperature was raised to 60° C., and then 176 g (0.62 mol) of 2,2,5,5-tetrachloro-1-isopropyl-[1,2,5]azadisilacyclopentane synthesized in step 2 was slowly added, After the addition was completed, stirring was performed for 12 hours under heating conditions of 65° C. to complete the reaction. The reaction mixture was filtered, and the filtrate was distilled under reduced pressure under 74° C. and 116.5 torr conditions to obtain 54 g (0.62 mol) of 2,2,5,5-tetrafluoro-1-isopropyl-[1,2,5]azadisilacyclopentane. (yield: 40%, GC purity: 97.6%).

¹H NMR (C₆D₆): 0.90 ppm (s, 4H, Si—CH₂—CH₂—Si), 1.26 ppm (d, 6H, N—CH(CH₃)₂), 3.58 ppm (m, 1H, N—CH(CH₃)₂),

¹³C NMR (C₆D₆): 0.49 ppm, 25.5 ppm, 45.3 ppm

²⁹Si NMR (in C₆D₆): −31.2 ppm (t, 2Si)

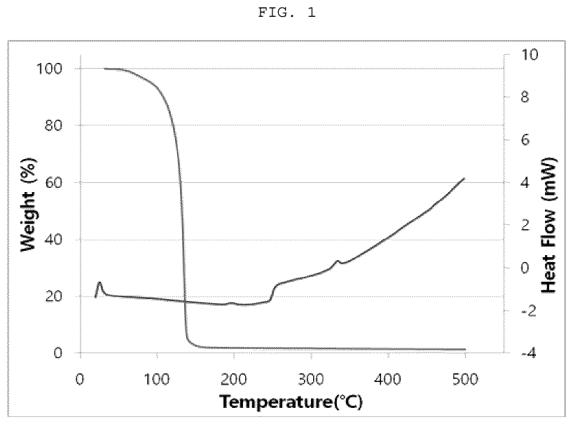

FIG. 1 shows results of thermogravimetric analysis (TGA) and differential scanning calorimeter (DSC) analysis of 2,2,5,5-tetrafluoro-1-isopropyl-[1,2,5]azadisilazanecyclopentane produced in Example 1. Referring to FIG. 1, it was found that the compound of Example 1 had a single evaporation step at about 150° C., and there was almost no residue mass at 150°° C., so that a rapid vaporization characteristic was shown. In addition, referring to the DSC graph of FIG. 1, it was found that thermal decomposition of the compound started after about 250° C., and the compound of Example 1 had excellent thermal stability and excellent volatility.

The cyclosilazane compound according to an exemplary embodiment of the present invention has excellent thermal stability, allows deposition of a thin film with a high thin film deposition rate even under low temperature conditions, and allows production of a high-quality silicon-containing thin film with high purity by a simple production process.

In addition, since the silicon-containing thin film produced from the cyclosilazane compound according to an exemplary embodiment has both excellent chemical and thermal stability and also has very low dielectric constant, it is expected to be usefully applied as an insulating film of a semiconductor device, in particular, a spacer of a semiconductor miniaturization process.

Hereinabove, although the present invention has been described by specific matters, examples, and comparative examples, they have been provided only for assisting in the entire understanding of the present invention. Therefore, the present invention is not limited to the above examples. Various modifications and changes may be made by those skilled in the art to which the present invention pertains from this description.

Therefore, the spirit of the present invention should not be limited to the above-described exemplary embodiments, and the following claims as well as all modifications equal or equivalent to the claims are intended to fall within the scope and spirit of the invention.

What is claimed is:

1. A cyclosilazane compound represented by the following Chemical Formula 1: 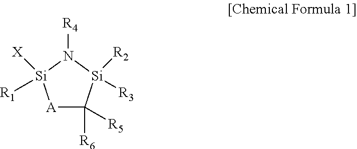
wherein:
X is halogen;
R₁ to R₃ are independently of one another hydrogen, halogen, C1-C7 alkyl, C2-C7 alkenyl, or C2-C7 alkynyl;
R₄ is hydrogen, halogen, C1-C7 alkyl, C2-C7 alkenyl, C2-C7 alkynyl, or —Si(R₁₁)(R₁₂)(R₁₃);
A is —(CR₇R₈)ₙ—;
R₅ to R₈ and R₁₁ to R₁₃ are independently of one another hydrogen, C1-C7 alkyl, C2-C7 alkenyl, or C2-C7 alkynyl; and
n is an integer of 1 to 5.

2. The cyclosilazane compound of claim 1, wherein:
X is fluoro;
R₁ to R₃ are independently of one another hydrogen, fluoro, C1-C4 alkyl, C2-C4 alkenyl, or C2-C4 alkynyl;
R₄ is hydrogen, fluoro, C1-C4 alkyl, C2-C4 alkenyl, C2-C4 alkynyl, or —Si(R₁₁)(R₁₂)(R₁₃);
A is —(CR₇R₈)ₙ—;
R₅ to R₈ and R₁₁ to R₁₃ are independently of one another hydrogen, C1-C4 alkyl, C2-C4 alkenyl, or C2-C4 alkynyl; and
n is an integer of 1 to 3.

3. The cyclosilazane compound of claim 1, wherein the cyclosilazane compound is represented by the following Chemical Formula 2: 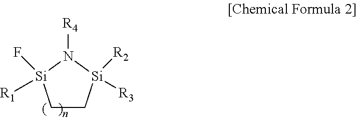
wherein:
R₁ to R₃ are independently of one another hydrogen, fluoro, C1-C7 alkyl, C2-C7 alkenyl, or C2-C7 alkynyl;
R₄ is hydrogen, fluoro, C1-C7 alkyl, C2-C7 alkenyl, C2-C7 alkynyl, or —Si(R₁₁)(R₁₂)(R₁₃);
R₁₁ to R₁₃ are independently of one another hydrogen, C1-C7 alkyl, C2-C7 alkenyl, or C2-C7 alkynyl; and
n is an integer of 1 to 5.

4. The cyclosilazane compound of claim 3, wherein:
R₁ to R₃ are independently of one another hydrogen, fluoro, or C1-C4 alkyl;
R₄ is hydrogen, fluoro, C1-C4 alkyl, or —Si(R₁₁)(R₁₂)(R₁₃);
R₁₁ to R₁₃ are independently of one another hydrogen or C1-C4 alkyl; and
n is an integer of 1 to 3.

5. The cyclosilazane compound of claim 1, wherein the cyclosilazane compound is represented by the following Chemical Formula 3: 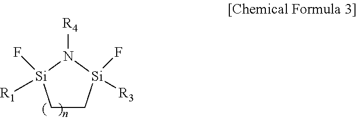
wherein:
R₁ and R₃ are independently of each other hydrogen, fluoro, C1-C7 alkyl, C2-C7 alkenyl, or C2-C7 alkynyl;
R₄ is hydrogen, fluoro, C1-C7 alkyl, C2-C7 alkenyl, C2-C7 alkynyl, or —Si(R₁₁)(R₁₂)(R₁₃);
R₁₁ to R₁₃ are independently of one another hydrogen, C1-C7 alkyl, C2-C7 alkenyl, or C2-C7 alkynyl; and
n is an integer of 1 to 5.

6. The cyclosilazane compound of claim 5, wherein:
R₁ and R₃ are independently of each other hydrogen, fluoro, or C1-C4 alkyl;
R₄ is hydrogen, fluoro, C1-C4 alkyl, or —Si(R₁₁)(R₁₂)(R₁₃);
R₁₁ to R₁₃ are independently of one another hydrogen or C1-C4 alkyl; and
n is an integer of 1 to 3.

7. The cyclosilazane compound of claim 1, wherein the cyclosilazane compound is selected from the group consisting the following structures:

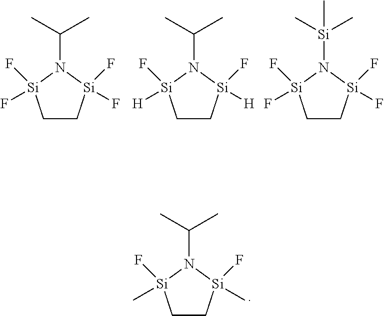

8. A composition for depositing a silicon-containing thin film, the composition comprising the cyclosilazane compound of claim 1.

9. A method of producing a silicon-containing thin film, using a cyclosilazane compound represented by the following Chemical Formula 1 or a composition for depositing a silicon-containing thin film including the cyclosilazane compound represented by the following Chemical Formula 1: 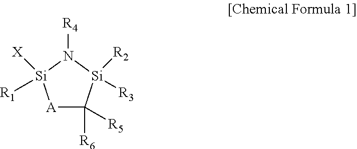
wherein:
X is halogen;
R₁ to R₃ are independently of one another hydrogen, halogen, C1-C7 alkyl, C2-C7 alkenyl, or C2-C7 alkynyl;
R₄ is hydrogen, halogen, C1-C7 alkyl, C2-C7 alkenyl, C2-C7 alkynyl, or —Si(R₁₁)(R₁₂)(R₁₃);
A is —(CR₇R₈)ₙ—;
R₅ to R₈ and R₁₁ to R₁₃ are independently of one another hydrogen, C1-C7 alkyl, C2-C7 alkenyl, or C2-C7 alkynyl; and
n is an integer of 1 to 5.

10. The method of claim 9, wherein the silicon-containing thin film is a fluorine and silicon-containing thin film.

11. The method of claim 10, wherein the fluorine and silicon-containing thin film comprises fluorine in an amount of 0.5 at % or more.
